(19) United States
(12) Patent Application Publication
(10) Pub. No.: US 2025/0183887 A1
(43) Pub. Date: Jun. 5, 2025

(54) TREATMENT METHOD OF POWER SEMICONDUCTOR MODULE

(71) Applicant: MITSUBISHI ELECTRIC CORPORATION, TOKYO (JP)

(72) Inventor: Julio BRANDELERO, RENNES Cedex 7 (FR)

(73) Assignee: MITSUBISHI ELECTRIC CORPORATION, TOKYO (JP)

(21) Appl. No.: 18/838,789

(22) PCT Filed: Jul. 22, 2022
(86) PCT No.: PCT/JP2022/029217

§ 371 Date: Aug. 15, 2024

(30) Foreign Application Priority Data
Mar. 23, 2022 (EP) 22305351.3

(51) Int. Cl. H03K 17/14; H03K 17/16; H03K 17/18

(52) U.S. Cl. CPC H03K 17/145; H03K 17/165; H03K 17/18

(57) ABSTRACT

A treatment method of a power semiconductor module comprising at least one semiconductor element including a Metal-Oxide-Semiconductor element and/or a Metal-Insulator-Semiconductor element, said method comprising:
a. acquiring a first value V_{soh,0} corresponding, to an initial state of health of a gate oxide of the module;
b. acquiring a second value V_{soh,X} corresponding, to a current state of health of a gate oxide of the module;
c. deducing
an ON-state gate voltage V_{CC} or an OFF-state gate voltage V_{EE}, and
a delay time of the turn-on t_{ON} or a delay time of the turn-off t_{OFF}
in function of said acquired first value V_{soh,0} and said second value V_{soh,X};
d. generating at least one control signal configured to apply the deduced gate voltage V_{CC} or V_{EE} to the module during the deduced delay time t_{ON} or t_{OFF}.

### TECHNICAL FIELD

This disclosure pertains to the field of monitoring, limiting, slowing down and/or reducing the intrinsic degradation of power semiconductors during operational service.

### BACKGROUND ART

The gate oxide quality of the power semiconductor modules during its operational life is known as a key parameter for the reliability concern of such devices.

For SiC MOSFET in particular, it seems that the gate oxide (GOX) film is a key point of the reliability: SiC MOSFET devices have a failure probability up to four orders of magnitude than Si MOSFET.

Decreasing the positive gate-source voltage could increase the reliability of the devices. A negative bias is commonly used as a countermeasure to avoid the self-turn-on of a device during the switching-on of a series electrically connected device. However, due to some idle time of the power semiconductor, a negative bias can be applied for several hours which will lead to a decrease on the threshold voltage. This variation is critical in the initial seconds on the converter start switching again. In addition, gate over-voltages occur during the switching times of the gate, which also contributes to a shift on the threshold voltage.

There are known solutions to improve the substrate defect density, and theoretically the reliability such: limitation on the gate oxide field in blocking mode and in on-state, avoidance of voltage spicks and SiC/SiO₂ interface passivation. However, the known solutions to maintain a gate oxide quality have various negative effects in some operational conditions of the power semiconductor modules.

### SUMMARY OF INVENTION

This disclosure improves the situation.

It is proposed a treatment method of a power semiconductor module comprising at least one semiconductor element including a Metal-Oxide-Semiconductor element and/or a Metal-Insulator-Semiconductor element, said method comprising:
a. acquiring a first value V_{soh,0} corresponding to an initial state of health of a gate oxide of the module;
b. acquiring a second value V_{soh,X} corresponding to a current state of health of a gate oxide of the module;
c. deducing
an ON-state gate voltage V_{CC} or an OFF-state gate voltage gate voltage V_{EE}, and
a delay time of the turn-on t_{ON} or a delay time of the turn-off t_{OFF} in function of said acquired first value V_{soh,0} and said second value V_{soh,X};
d. generating at least one control signal configured to apply the deduced gate voltage V_{CC} or V_{EE} to the module during the deduced delay time t_{ON} or t_{OFF}.

In another aspect, it is proposed a power semiconductor module comprising a single Metal-Oxide-Semiconductor element or a set of Metal-Oxide-Semiconductor elements or a single Metal-Insulator-Semiconductor element or a set of Metal-Insulated-Semiconductor elements, said module being arranged to implement such a method.

In another aspect, it is proposed a computer software comprising instructions to implement the method as defined here when the software is executed by a processor. In another aspect, it is proposed a computer-readable non-transient recording medium on which a software is registered to implement the method as defined here when the software is executed by a processor.

The following features, can be optionally implemented, separately or in combination one with the others:

The method further comprises the following preliminary operation:
switching said at least one semiconductor element
from an ON-state to an OFF-state, according to a control logic signal with a zero or negative gate voltage V_{EE} and with a delay time for the turning-off t_{OFF}; or
from an OFF-state to an ON-state, according to a control logic signal with a positive gate voltage V_{CC} and with a delay time for the turning-on t_{ON}.

The sign of the applied gate voltage V_{CC} or V_{EE} depends on the ON/OFF state of said at least one semiconductor element.

Criteria to deduce the delay time of the turn-on tₒₙ or the delay time of the turn-off t_{OFF} in function of said acquired first value V_{soh,0} and said acquired second value V_{soh,X} includes the following:
if the acquired second value V_{soh,X} is superior to the acquired first value V_{soh,0},
the delay time of the turn-off t_{OFF} is increased with respect to a previous value of the delay time of the turn-off t_{OFF};
if the acquired second value V_{soh,X} is inferior to the acquired first value V_{soh,0}, the delay time of the turn-off t_{OFF} is decreased with respect to a previous value of the delay time of the turn-off t_{OFF}.

Criteria to deduce the ON-state gate voltage V_{CC} or an OFF-state gate voltage gate voltage V_{EE} in function of said acquired first value V_{soh,0} and said acquired second value V_{soh,X} includes the following:
if the acquired second value V_{soh,X} is superior to the acquired first value V_{soh,0}, the ON-state gate voltage V_{CC} is increased with respect to a previous value of the ON-state gate voltage V_{CC}, and the increasing is proportional or equal to the difference between the acquired first value V_{soh,0} and the acquired second value V_{soh,X}.

Criteria to deduce the ON-state gate voltage V_{CC} or an OFF-state gate voltage gate voltage V_{EE} in function of said acquired first value V_{soh,0} and said acquired second value V_{soh,X} includes the following:
if the acquired second value V_{soh,X} is superior to the acquired first value V_{soh,0},
the OFF-state gate voltage V_{EE} is decreased with respect to a previous value of the OFF-state gate voltage V_{EE};
if the acquired second value V_{soh,X} is inferior to the acquired first value V_{soh,0},
the OFF-state gate voltage V_{EE} is increased with respect to a previous value of the OFF-state gate voltage V_{EE};
if the acquired second value V_{soh,X} is equal to the acquired first value V_{soh,0},
the OFF-state gate voltage V_{EE} is maintained equal to a previous value of the OFF-state gate voltage V_{EE}.

Criteria to deduce the ON-state gate voltage V_{CC} or an OFF-state gate voltage gate voltage V_{EE} in function of said acquired first value V_{soh,0} and said acquired second value V_{soh,X} includes the following:
if the acquired second value V_{soh,X} is superior to the acquired first value V_{soh,0}, the OFF-state gate voltage V_{EE} is decreased with respect to a previous value of the OFF-state gate voltage V_{EE};
if the acquired second value V_{soh,X} is inferior to the acquired first value V_{soh,0}, the ON-state gate voltage V_{CC} is increased with respect to a previous value of the ON-state gate voltage V_{CC};
if the acquired second value V_{soh,X} is equal to the acquired first value V_{soh,0}, the ON-state gate voltage V_{CC} and the OFF-state gate voltage V_{EE} are each reinitialized to their respective value by default.

The method further comprises the following operation:
when a reverse conduction of the semiconductor element is detected, generating at least one control signal configured to apply the deduced gate voltage V_{CC} or V_{EE} to the module.

At least two second values V_{soh,X} and V_{soh,X+1} are acquired during the lifetime of the module, and a criteria to deduce the ON-state gate voltage V_{CC} or an OFF-state gate voltage gate voltage V_{EE} in function of said acquired first value V_{soh,0} and said acquired second values V_{soh,X} and V_{soh,X+1} includes the following:
if the temporal derivative of the said acquired second values dV_{soh,X}/dt is positive, the ON-state gate voltage V_{CC} is decreased with respect to a previous value of the ON-state gate voltage V_{CC} and/or the OFF-state gate voltage V_{EE} is decreased with respect to a previous value of the OFF-state gate voltage V_{EE};
if the temporal derivative of the said acquired second values dV_{soh,X}/dt is negative, the ON-state gate voltage V_{CC} is increased with respect to a previous value of the ON-state gate voltage V_{cc} and/or the OFF-state gate voltage V_{EE} is increased with respect to a previous value of the OFF-state gate voltage V_{EE}.

Criteria to deduce the delay time of the turn-on t_{ON} or the delay time of the turn-off t_{OFF} is further dependent from the ON-state gate voltage V_{CC} and/or the OFF-state gate voltage gate voltage V_{EE}.

Other features, details and advantages will be shown in the following detailed description and on the figures.

### BRIEF DESCRIPTION OF DRAWINGS

FIG. 1 is a schematical representation of a physical phenomenon.

FIG. 2 is schematic representation of the evolution of some index during the lifetime of a power semiconductor element.

FIG. 3 is an example of a circuit with a semiconductor element.

FIG. 4 is a superposition of gate driver switching waveforms for various situations.

FIG. 5 is a circuitry according to an embodiment.

FIG. 6 is a graphic view of some values during an embodiment.

### DESCRIPTION OF EMBODIMENTS

### Main Problems to Solve

Bias temperature instability (BTI) is a reliability issue concerning the insulated gate power modules, such Metal-Oxide-Semiconductor-Field-Effect-Transistors (MOSFET), Insulated-Gate-Bipolar-Transistors (IGBT) and High-Electron-Mobility-Transistors (HEMT). In the SiC power semiconductor elements, this phenomenon is much more problematic during the device lifetime than in Si power semiconductor elements (approximately ten times higher), due to the reduced band offsets between the gate oxide and the power semiconductor occurrence and the carbon atoms degrading the atomically smooth Si/SiO₂ interface. The charge trapping also concerns the reliability in GaN HEMTs devices, due to the gate stack structure complexity.

The charge trapping can be a permanent or a transitory phenom which the main consequences of this reliability issue are:
i/ “On-state resistance RDS(on) increase”—leading to an over-loss dissipation on the devices/modules and an over-temperature during the power semiconductor elements operation which can be catastrophic for the integrity of the materials;
ii/ “Body diode threshold voltage”—leading to an over-loss dissipation on the element and an over-temperature during the power semiconductor operation;
iii/ “Off-state blocking leakage IDSS(off)”—that will generate extra losses on the element and can also lead to a catastrophic failure;
iv/ “Shoot-Through Currents”—given the change in the ON and OFF time delay. The initial dead time from power semiconductor cannot be enough to switch the series devices safely and create catastrophic short circuit failure.

In each previous concerns, the extra losses generated by the deterioration will increase the temperature of the power semiconductor which accelerates the degradation.

Identifying the gate oxide degradation under on-line operation of the power semiconductor is a key parameter to assess the reliability of such devices: from a test and safety assessment point of view (including standards) and dispatch/maintenance of the power converter.

### {Theory}

The flatband voltage V_{fb} is a voltage that when applied to a semiconductor element generates a flat energy band in the semiconductor and is determined by the following equation [Math. 1]:

$${V}_{f b} = {Φ}_{M S} - \frac{{Q}_{o x}}{{C}_{o x}} - \frac{1}{{ε}_{o x}} {\int }_{0}^{{t}_{ox}} {ρ}_{o x} ( x ) \cdot x \cdot dx . \qquad [ Math . 1 ]$$

Φ_{MS} is the work function difference between the gate metal material and the semiconductor material. Cₒₓ is the thin oxide capacitance. Qₒₓ is the total effective charge in the oxide. The last term of [Math. 1] is due to the charge density in the oxide.

Ones can note that the flatband voltage is affected by the presence of charges on the oxide-semiconductor interface. The charges presented in this interface are sensitive to the electric field formed on the channel. As the positive gate voltages generate a positive electrical field conducting to a negative charge accumulation on the oxide, the flatband voltage increases by the equation [Math. 1]. In an opposite way, as the negative gate voltages generate a negative electrical field conducting to a positive charge accumulation on the oxide, the flatband voltage decreases by the equation [Math. 1]. This phenomenon is called Bias Temperature Instability, or BTI. For a positive electrical field, it is called Positive Temperature Bias instability (PBTI). And for a negative electrical field, this is called Negative Temperature Bias Instability (NBTI).

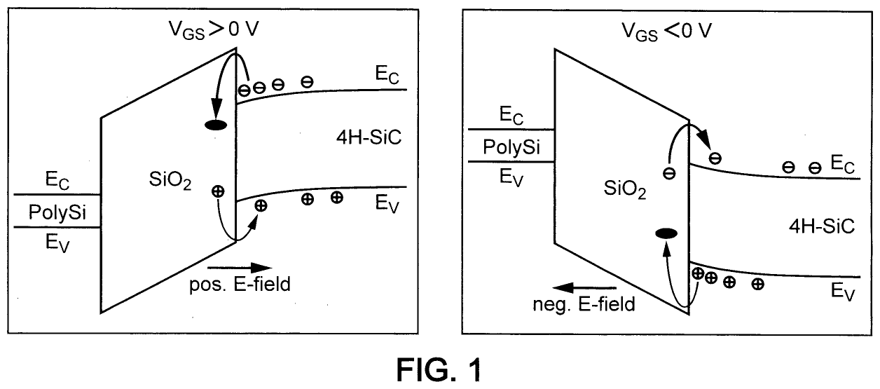

FIG. 1 is based on a figure published in the following paper: X. Zhong et al., “Bias Temperature Instability of Silicon Carbide Power MOSFET Under AC Gate Stresses” IEEE Transactions on Power Electronics, vol. 37, no. 2, pp. 1998-2008, February 2022, doi: 10.1109/TPEL.2021.3105272. FIG. 1 illustrates the above-described phenomena, the left part corresponding to a situation wherein the gate-source voltage V_{GS} is superior to 0 V, while the right part corresponds to a situation wherein the gate-source voltage V_{GS} is inferior to 0 V.

Despite the efforts during design to avoid the incorporation of charges on the oxide, during the lifetime of the power semiconductor element, positive or negative electrical fields will trap charges on the gate oxide. This phenomenon is hardly avoided in the case of SiC or GaN semiconductors materials where more interface states and fixed oxide charge appear after a high electric field application. The trapped charge is also significantly increased with a high switching frequency and/or by a hot device temperature.

One of the main consequences of the gate oxide deterioration is the evolution on the threshold voltage Vₜₕ that is described as per following equations [Math. 2] and [Math. 3].

$${V}_{t h} = {V}_{f b} + 2 {Φ}_{f} + \frac{\sqrt{4 \cdot {ε}_{s} \cdot q \cdot {N}_{a} \cdot {Φ}_{f}}}{{C}_{o x}} \qquad [ Math . 2 ]$$

$${Φ}_{f} = \frac{kT}{q} ln \frac{{N}_{a}}{ni} \qquad [ Math . 3 ]$$

Nₐ is the acceptor density in the substrate. εₛ is the semiconductor dielectric constant. k is the Boltzmanns constant. T is the temperature. ni is the intrinsic carrier concentration. Cₒₓ is the oxide capacitor value.

As the gate and the substrate doping and the oxide thickness are not affected by the voltage bias stress, the noticeable change on the threshold voltage Vₜₕ is related to the changes on the oxide charges and then can be monitored only by the measurement of the flatband voltage V_{fb} as per following equation [Math. 4].

$$Δ {V}_{th} = {V}_{th ( f r e s h )} - {V}_{th ( s t r e s s )} = {V}_{fb ( fresh )} - {V}_{fb ( stress )} \qquad [ Math . 4 ]$$

The changes on the gate oxide can be transitory or permanent. The transitory changes are related to the high frequency such the switching frequency on the range of the tens of kHz to hundreds of kHz. The permanent changes are related to period measured in several hours/days. The aggravation factors are the long OFF-state period, e.g. the idle time of the module, or the long ON-state period, such the solid-state power controller application (solid-state relay). Both modes have consequences on:
the conduction losses, as the transfer characteristic, from the gate voltage V_{g} to the main voltage V_{CE}, V_{DS}, and current I_{C}, I_{D}, is modified. This will impact the conduction losses of the power semiconductor element;
the switching times, as the threshold voltage is varying.

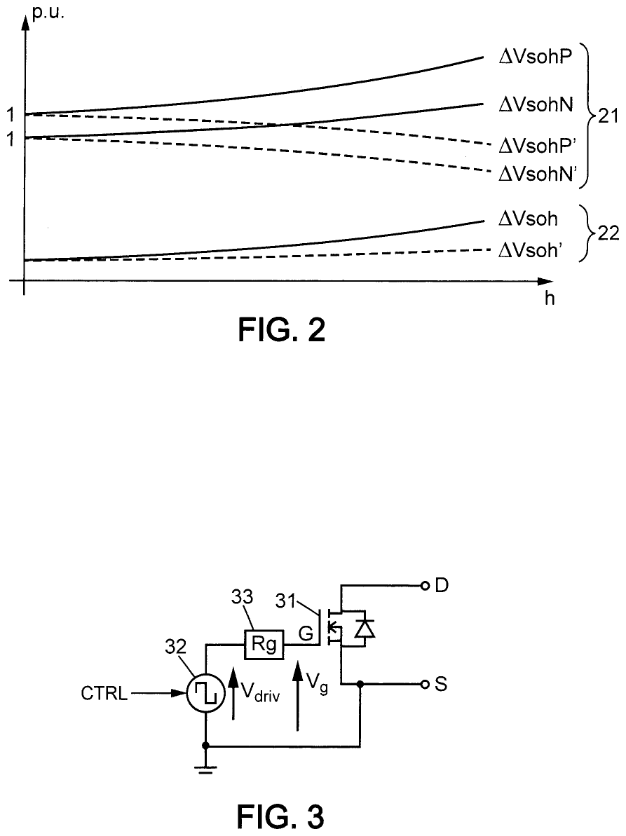

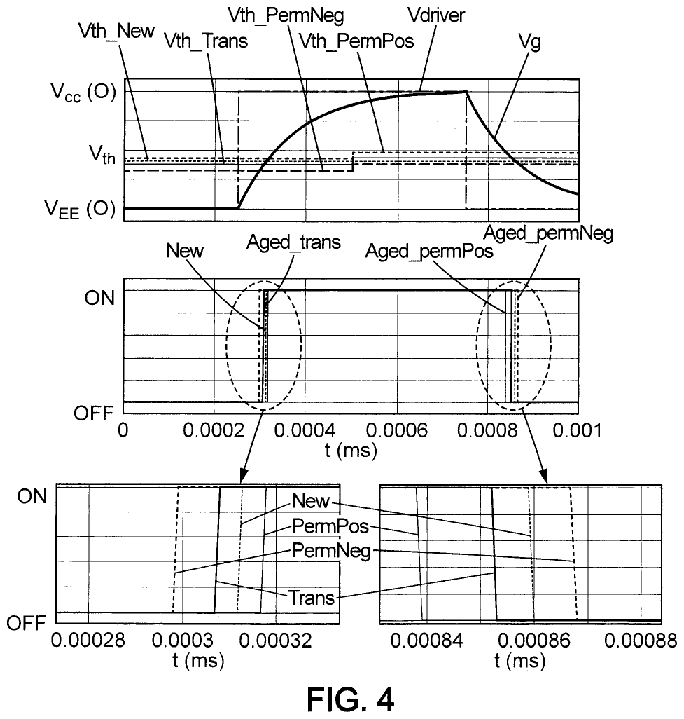

As a result of the gate oxide degradation, it can be seen in the FIG. 2, FIG. 3 and FIG. 4 the switching times are modified in function of the level of the threshold voltage Vₜₕ. FIG. 2 represents a classical circuit including a semiconductor element 31 (a transistor) wherein the gate voltage V_{g} is controlled with a voltage source 32 (V_{driv}) and a gate resistance 33 (R_{g}) on the gate branch G. Graphics of FIG. 4 show comparative switching waveforms in function of the situation of a same semiconductor element 31:
the index “New” corresponds to a situation wherein the semiconductor element 31 is new (nominal situation);
the index “PermPos” corresponds to the effect of a permanent and positive gate oxide deterioration;
the index “PennNeg” corresponds to the effect of a permanent and negative gate oxide deterioration;
the index “Trans” corresponds to the effect of a transitory gate oxide deterioration.

FIG. 2 represents the evolution of some indexes during the lifetime (in days) when the gate is driven with a standard pattern, the indexes 21 corresponding to permanent changes and the indexes 22 corresponding to transitory changes:
positive gate bias ΔVsohP;
negative gate bias ΔVsohN;
transitory state of health change ΔVsoh=ΔVsohP−ΔvsohN.

The solid lines correspond to index “PermPos” of FIG. 4 while dotted lines and indexes with a “prime” (′) correspond to “PermNeg” of FIG. 4.

The defaults generated at the turn-on state are:
caused by a decrease of the threshold voltage Vₜₕ, the turn-on taking place before the desired time. A short-through current can appear on a half-bridge configuration where a series power-semiconductor element works in a complementary state;
caused by an increase of the threshold voltage Vₜₕ, the turn-on taking place after the desired time. A body-diode conduction will occurs increasing the total system losses.

The defaults generated at the turn-off state are:
caused by an increase of the threshold voltage Vₜₕ, the turn-off taking place before the desired time. A body-diode conduction will occurs increasing the total system losses;
caused by a decrease of the threshold voltage Vₜₕ, the turn-off taking place after the desired time. A short-through current can appear on a half-bridge configuration where a series power-semiconductor element works in a complementary state.

In terms of system safety, the anticipation of the turn-on and the delay of turn-off can cause severe damage on the devices given a large short-through current.

An aim, here, is to remove, or at least reduce, the impact of the gate oxide deterioration by acting on the control gate driver voltage that will result in a gate voltage to control the power semiconductor element. Furthermore, a dedicate gate voltages are controlled to also reduce and/or remove the gate oxide deterioration.

### DESCRIPTION OF EMBODIMENTS

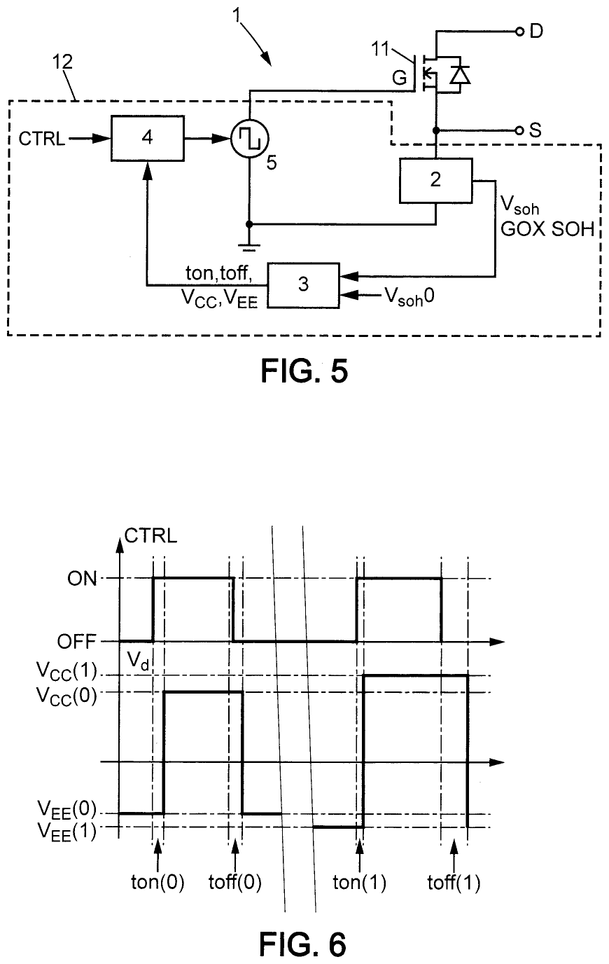

It is referred to FIG. 5 and FIG. 6. In the following, power semiconductor modules 1 are assembly comprising at least one Metal-Oxide-Semiconductor (MOS) element or a Metal-insulator-Semiconductor (MIS). Even if the module 1 comprises a plurality of MOS elements, there are considered as single one in the following: there is a common gate G, a common source S and a common drain D. For this reason, it is referred to a single gate, a single source and a single drain in the following without distinction of embodiments with a single one or a plurality of MOS elements. The word “power” is used in its general meaning of the technical field of energy conversion (power electronics).

An aim of the following method is to adapt the gate control voltages and switching timings to reduce or neutralize the charge trapping effects while maintaining as much as possible output characteristics V_{DS} and I_{D}. The proposed method can be used in operational conditions, typically not only on a test bench but when the module is integrated and interconnected in its operational and industrial environment.

The module 1 comprises at least one semiconductor element 11 (here a transistor) and a control circuitry 12 including:
means for detecting the state of health of the gate oxide, here for example a detection module 2;
means for comparing the current state of health of the gate oxide with the initial state of health, here for example a calculation module 3,
means to decide on the delay time of the turn-on tₒₙ, the delay time of the turn off t_{off}, the ON state voltage V_{CC}, and the OFF state voltage V_{EE}, here for example the calculation module 3;
means for convert the control signal CTRL into the required gate signal, here for example an actuation module 4;
means to drive the gate, here for example a controllable gate driver voltage source 5.

Only as examples, the calculation module 3 can comprise a digital or an analogue controller. The actuation module 4 can comprise a programmable delay generator, as for example the commercial reference “AD9500”, or the delay can be generated by an FPGA. The controllable gate driver voltage source 5 can be a variable voltage source, as for example a linear gain control amplifier. The gate driver voltage source can be a push-pull, a totem-pole voltage source or a class B amplifier.

The method comprises the following operations:
a. acquiring a first value V_{soh,0} corresponding to an initial state of health of a gate oxide of the module 1;
b. acquiring a second value V_{soh,X} corresponding to a current state of health of a gate oxide of the module 1;
c. deducing a gate voltage V_{CC} or V_{EE} and a delay time t_{ON} or t_{OFF} in function of said acquired first value V_{soh,0} and said second value V_{soh,X};
d. generating at least one control signal CTRL configured to apply the gate voltage V_{CC} or V_{EE} to the module 1 during the delay time t_{ON} or t_{OFF}.

The acquisition of the states of health (the initial one V_{soh,0} and/or the current one V_{soh,X}) can be made by the detection module 2. For example, fast Measure-Stress-Measure (MSM) techniques can be executed to determine the current state of health of the gate oxide. The measures are made just after the stress. Examples are proposed:
1. measure of the threshold voltage Vₜₕ;
a kelvin-source voltage, generated by the temporal derivative of the current di/dt during the semiconductor element 11 turn-on/off switching times, is used to trigger the gate-source voltage V_{GS} measure that is taken as Vₛₒₕ;
2. measure of the turn-on/off delays: a kelvin-source voltage, generated by the temporal derivative of the current di/dt during the semiconductor element 11 turn-on/off switching times, is used to trigger a timer that is converted to a Vₛₒₕ.

Such MSM techniques are advantageous because only gate connections are necessary. But, in various embodiments, other techniques to acquire the state of health can be used.

The classical voltage values during ON state, V_{CC}, is around 15V (classically between 10V and 20V) and the OFF state, V_{EE}, is around −5V (classically between −20V and 0V).

In the embodiment shown on FIG. 5, the calculation module 3 is configured to receive the current state of health V_{soh,X} from the detection module 2. The calculation module 3 is further configured to compare the received current state of health V_{soh,X} to the initial state of health V_{soh,0}. The gate driver voltage source 5 is configured to control the gate of the semiconductor element 11, between ON and OFF states following the external control signal CTRL modified by the actuation module 4. The instants of the transition between the OFF and ON states, that alternates within a switching period, are determined by the external control signal CTRL, with a delay t_{ON} and t_{OFF} and an amplitude V_{CC} and V_{EE} imposed by the calculation module 3. As a result, the applied gate driver voltage is modified in time and amplitude. As an example, the amplitude variation is between 0V and 5V, and the time is between 0 ns and 500 ns (see FIG. 6).

In some embodiments, the method further comprises the following preliminary operation:
switching said at least one Metal-Oxide-Semiconductor element (11)
from an ON state to an OFF state, according to a CTRL logic signal with a zero or negative gate voltage V_{EE} and with a delay time for the turning-off t_{off}; or
from an OFF state to an ON state, according to a CTRL logic signal with a positive gate voltage V_{CC} and with a delay time for the turning-on tₒₙ.

In some embodiments, a part of the method forms an iterative loop such that, after the control signal CTRL generation of a preceding loop, the method is reiterated as a current loop such that the series of operations b to d are reiterated at least one time, starting from an acquisition of a second value V_{SOH,X+1} a second time. In the examples, the first value V_{soh,0} is not reacquired a second time and is reused for each loop. In the following, the indexes “X” and “X+1” are used to designate respectively an iteration and the successive one.

In the following, some various examples will be presented about the manner to deduce the gate voltage V_{CC} or V_{EE} and the delay time t_{ON} or t_{OFF} in function of acquired first value V_{soh,0} and second value V_{soh,X} (operation c), and/or in function of successive values V_{soh,X} and V_{soh,X+1}. An embodiment can comprise a combination of features issued from such examples.

### Example A

The series of operations, including the acquisition of the gate oxide state of health Vₛₒₕ, can be made only once on a switching period (succession of ON+OFF state). In various embodiments, it can be made twice on a switching period, a first one for the ON state, a second one for the OFF state.

Advantageous, the ON and OFF switching times can be adapted according to the permanent state of health of the gate oxide. In this last case, an ON state of health V_{sohP} and an OFF state of health V_{sohN} are defined respectively for the ON and OFF states. Advantageous, the ON and OFF switching times are adapted according to the permanent and transitory state of health of the gate oxide.

In some embodiments, the gate oxide state of health Vₛₒₕ is acquired at a fixed time delay after the turn-off of the semiconductor element 11. The ON state of health V_{sohP} can be acquired just before or just after the turn-off, for example within 10 μs before/after the turn-off.

In some embodiments, the OFF state of health V_{sohN} is acquired just before the turn-on, for example within 10 μs before the turn-on. Alternatively, the OFF state of health V_{sohN} can be made continually (within 1.0 μs between estimations) during the off-time. The last value acquired before the turn-on is kept. In addition, an external signal can control when the OFF state of health V_{sohN} should be acquired.

The initial state of health V_{soh,0} of the semiconductor element 11 can be obtained during the first hours of operation of the module 1, for example 2 hours. In various embodiments, it can be obtained during the commissioning phase for each semiconductor element. Or it can be pre-programed based on the measurements in a batch of representative power semiconductor elements, like a nominal value.

### Example B

In some embodiments, it is possible to optimize the switching instants of the semiconductor element 11 in face of the gate oxide deterioration. For this aim, the delay time of the switching sequence can be adjusted in case the gate oxide state of health voltage Vₛₒₕ shifts during the module 1 operation (along the lifetime) to avoid shoot-through currents and excessive losses due to body diode conduction. Advantageous, the switching times are adaptive related to the gate oxide deterioration. This enables to reduce the design margins and increase the module efficiency.

To do that, it is possible to change in time, the rinsing edge and the falling edge of the signal that controls the semiconductor element 11. For example:
If V_{soh,X}>V_{soh,0}, the delay t_{ON} is decreased and the delay t_{OFF} is increased;
If Vs_{soh,X}<V_{soh,0}, the delay t_{ON} is increased and the delay t_{OFF} is decreased.

In the initial conditions, t_{ON} and t_{OFF} can be set to an initial value t_{ON,0} and t_{OFF,0}, e.g. 300 ns and 200 ns respectively.

In case the state of health of the gate oxide corresponds to the threshold voltage Vₜₕ, the applied t_{ON} and t_{OFF} delays can be calculated as it follows in [Math. 5] and [Math. 6], or in [Math. 5] and [Math. 7].

$${t}_{O N} = {t}_{ON , 0} + Δ {t}_{O N} ; {t}_{O F F} = {t}_{O F F , 0} + Δ {t}_{O F F} \qquad [ Math . 5 ]$$

$$Δ {t}_{O N} = Rg \cdot Ciss \cdot ln ( \frac{{V}_{soh , X} - {V}_{C C}}{{V}_{soh , X} - {V}_{C C}} ) ; \\ Δ {t}_{OFF} = Rg \cdot Ciss \cdot ln ( \frac{{V}_{soh , X} - {V}_{E E}}{{V}_{soh , X} - {V}_{E E}} ) \qquad [ Math . 6 ]$$

$$Δ {t}_{O N} = Rg \cdot Ciss \cdot ln ( \frac{{V}_{s ohP , X} - {V}_{CC}}{{V}_{s o hP , X} - {V}_{CC}} ) ; \\ Δ {t}_{OFF} = Rg \cdot Ciss \cdot ln ( \frac{{V}_{s o hN , X} - {V}_{E E}}{{V}_{s o h N , X} - {V}_{E E}} ) \qquad [ Math . 7 ]$$

Rg being the external and internal total gate resistances and Ciss being the input gate capacitance that can be approximated by the oxide capacitance. When it is combined with the example where the state of heath is made twice in a switching period, the V_{sohP,X} is used for determining the turn-ON delay t_{ON} and the V_{sohN,X} is used to determine the turn-off delay t_{OFF}.

In the case the state of health corresponds to the flatband voltage V_{fb}, the equation [Math. 2] and [Math. 3] are used in the place of the Vₛₒₕ variable in the previous equation.

In the system, delays t_{ON} and or t_{OFF} cannot be negative values. Thus, the t_{ON,0} and t_{OFF,0} considers the maximum delay time variation of the semiconductor element considering a maximum deterioration of its gate oxide state of health during the lifetime. In this case, the initial delay t_{OFF,0} is calculated as a function of the minimum gate oxide state of health and the initial delay t_{ON,0} is calculated as the maximum value as t_{OFF} plus a security margin “dead time” that integrates the turn-on and turn-off classical delays for a non-deteriorate device as [Math. 8].

$${t}_{OFF , 0} = Rg \cdot Ciss \cdot ln ( \frac{min ( {V}_{soh , X} ) - {V}_{E E}}{{V}_{s oh , 0} - {V}_{E E}} ) ; \\ {t}_{O N , 0} = Rg \cdot Ciss \cdot ln ( \frac{max ( {V}_{s oh , X} ) - {V}_{C C}}{{V}_{s oh , X} - {V}_{C C}} ) + Deadtime \qquad [ Math . 8 ]$$

### Example C

In some embodiments, it is possible to maintain constant the conduction loses of the semiconductor elements in face of a gate oxide deterioration. For this aim, the positive gate voltage V_{CC} is adjusted in time for the case the state of health of the gate oxide shifts during the semiconductor element operation, avoiding excessive heat on the semiconductor element. Advantageous, the initial positive gate voltage V_{CC,0} can be designed lower than a nominal value to avoid fast gate oxide deterioration. In other words, the increasing of the positive gate voltage V_{CC} is made progressively/iteratively to avoid overvoltage and corresponding useless heating.

For example:
If V_{soh,X+1}>V_{soh,X}, increase the positive gate voltage V_{CC,X+1} with respect to its previous value V_{CC,X}.

In order to not cause more damage to the gate oxide by the application of a more positive voltage, this condition/rule can be activated only when the semiconductor element is loaded by more than a predetermined portion (for example 60%) of the initial maximum load design. The “load” in this context can be, for example, the main collector/drain current or the junction temperature.

For example, the increasing value is equal to the evolution of the state of health absolute difference between the initial state of health and the current state of health:

$${V}_{CC , X} = {V}_{C C , 0} + {V}_{soh , X} - {V}_{s o h , 0} .$$

### Example D

In some embodiments, it is possible to reduce (not necessarily stop or repair) the deterioration of gate oxide by applying an opposite gate voltage bias under the power semiconductor module operation. Advantageous, the gate charge trapped can be reduced by applying a different gate voltage than the classical operation without disturbing normal operation. Thus, any charge accumulation that leads to a deterioration of the power semiconductor operation mode is slowed before any irreversible failure which could be catastrophic.

For example:
If V_{soh,X}>V_{soh,0} applying a lower voltage during the OFF state (V_{EE,X}<V_{EE,0})
If V_{soh,X}<V_{soh,0} applying a higher voltage during the OFF state (V_{EE,X}>V_{EE,0})
If V_{soh,X}=V_{soh,0} applying the same voltage during the OFF state (V_{EE,X}=V_{EE,0})

By decreasing the negative gate bias on the semiconductor element (V_{EE}) more holes are captured in the gate oxide and the positive bias instability is compensated by a negative bias instability reducing the speed of the deterioration. In the opposite way, by increasing the negative gate bias on the semiconductor element, less holes are captured in the gate oxide and the negative bias instability is reduced.

In first examples: V_{EE,X}=V_{EE,0}+V_{soh,0}−V_{soh,X}. V_{EE}=−5V; V_{soh,0}=3V; V_{soh,X}=4V, then V_{EE,X}=−6V V_{EE}=−5V; V_{soh,0}=3V; V_{soh,X}=2V, then V_{EE,X}=−4V

In second examples: V_{EE,X}=V_{EE,0}+k (V_{soh,0}−V_{soh,X}), where k is a predetermined factor, for example 0.05.

### Example E

In some embodiments, it is possible to stop (not only reduce but not necessarily repair) further deterioration of gate oxide of the semiconductor element by changing the negative and/or positive gate voltage bias under the semiconductor module operation. Advantageous, the gate charge trapped can be slowed down by applying a different gate voltage than the classical operation. Thus, any charge accumulation that leads to a deterioration of the power semiconductor operation mode is stopped before any irreversible failure which could be catastrophic.

For example:
If dV_{soh,X}/dt>0, applying a lower voltage V_{EE,X} during the OFF state and/or applying a lower voltage V_{CC,X} during the ON state
If dV_{soh,X}/dt<0, applying a higher voltage V_{EE,X} during the OFF state and/or applying a higher voltage V_{CC,X} during the ON state.

By reducing the negative gate bias on the semiconductor element, more holes are captured in the gate oxide and the positive bias instability is compensated by a negative bias instability reducing the speed of the deterioration. In the opposite way, by increasing the negative gate bias on the semiconductor element, less holes are captured in the gate oxide and the negative bias instability is reduced.

The voltages V_{EE,X}, respectively V_{CC,X}, can be calculated in function of the derivative of the V_{soh,X}, a predetermined gain K and the previous values V_{EE,0}, respectively V_{CC,0}. For example: V_{EE,X}=V_{EE,0}+K_{EE} dV_{soh,X}/dt, and V_{CC,X}=V_{CC,0}+K_{CC} dV_{soh,X}/dt. And for example: K_{EE}=K_{CC}=Imin/V.

In various example, different gains K can be used according to the sign of the derivative:

$$If {dV}_{soh , X} / dt > 0 , {K}_{C C} < {K}_{E E}$$

$$If {dV}_{soh , X} / dt < 0 , {K}_{C C} > {K}_{E E} .$$

Such conditions/rules limit the further increase of the conduction losses when a positive temperature bias instability is present (dV_{soh,X}/dt>0). And it limits the impact on the self-turn-on (by the increase of V_{EE}) when the negative gate bias is present (dV_{soh,X}/dt<0).

### Example F

In some embodiments, it is possible to apply a recovery sequence to the power semiconductor module to remove the positive or negative Bias Temperature Instability. Advantageous, the gate charge trapped can be removed from the gate oxide by applying a different gate voltage than the classical operation and for only a limited time. Thus, any charge accumulation that leads to a deterioration of the power semiconductor operation mode is stopped before any irreversible failure which could be catastrophic. Furthermore, the restoration can be made in a short step of time avoiding the deterioration to propagate.

For example:
If V_{soh,X}>V_{soh,0}, applying a more negative voltage (V_{EE,X}<V_{EE,0}) during the OFF state;
If V_{soh,X}<V_{soh,0}, applying a higher (positive) voltage (V_{CC,X}>V_{CC,0}) during the OFF state;
If V_{soh,X}=V_{soh,0}, applying the same voltages (V_{EE,X}=V_{EE,0}; V_{CC,X}=V_{CC,0}) during the OFF, respectively ON, state.

This mode can be applied during the idle state of the power semiconductor module, when V_{EE} and V_{CC} are kept during several hours. To accelerate the recovery, the power semiconductor module can be heated.

### Example G

In some embodiments, it is possible to apply an OFF-state or an ON-state gate voltage V_{EE} and/or V_{CC} during the reverse conduction of the semiconductor element, depending on the shift of the state of health (for example the flatband voltage V_{fb}). Advantageous, this can be implemented on line in applications such as inverters where the device is operating in both forward and reverse conduction mode.

### Example H

In some embodiments, it is possible to change the timing according to the degradation and the new applied voltage V_{CC} and V_{EE}. In other words, the value of the timings depends on the applied voltages. Advantageous, all the output characteristic of the semiconductor element is maintained constant.

The delay time is calculated based on the initial and deteriorate gate oxide state of health and initial positive and negative gate voltage, V_{CC}, V_{EE} and determined positive and negative gate voltage, V_{CC,X}, V_{EE,X}.

The timing is calculated according to [Math. 9] and [Math. 10], or [Math. 9] and [Math. 11].

$${t}_{O N} = {t}_{O N , 0} + Δ {t}_{ON , 1} ; {t}_{O F F} = {t}_{OFF , 0} + Δ {t}_{OFF , 1} \qquad [ Math . 9 ]$$

$$Δ {t}_{O N} = Rg \cdot Ciss \cdot ln ( \frac{{V}_{soh , X} - {V}_{CC , X}}{{V}_{E E , X} - {V}_{CC , X}} \cdot \frac{{V}_{EE , 0} - {V}_{CC , 0}}{{V}_{s oh , 0} - {V}_{CC , 0}} ) ; Δ {t}_{OFF} = Rg \cdot Ciss \cdot ln ( \frac{{V}_{s oh , X} - {V}_{EE , X}}{{V}_{CC , X} - {V}_{EE , X}} \cdot \frac{{V}_{CC , 0} - {V}_{EE , 0}}{{V}_{s oh , 0} - {V}_{EE , 0}} ) \qquad [ Math . 10 ]$$

$$Δ {t}_{ON} = Rg \cdot Ciss \cdot ln ( \frac{{V}_{s o hP , X} - {V}_{CC , X}}{{V}_{EE , X} - {V}_{CC , X}} \cdot \frac{{V}_{EE , 0} - {V}_{CC , 0}}{{V}_{s o hP , 0} - {V}_{CC , 0}} ) ; Δ {t}_{O F F} = Rg \cdot Ciss \cdot ln ( \frac{{V}_{s o hN , X} - {V}_{EE , X}}{{V}_{CC , X} - {V}_{E E , X}} \cdot \frac{{V}_{CC , 0} - {V}_{EE , 0}}{{V}_{sohN , 0} - {V}_{EE , 0}} ) \qquad [ Math . 11 ]$$

As particularly advantageous embodiments, the features of example H can be combined with features of Examples C and D. For example:
for an Rg=12Ω; Ciss=10e−9 and the following initial conditions, V_{CC,0}=15V; V_{EE,0}=−5V; V_{sohP}=V_{sohN}=3V, t_{ON,0}=500 ns; t_{OFF,0}=250 ns; t_{ON,0}=298.6 ns;
For a deteriorate state of health V_{sohP,X}=V_{sohN,X}=4; The features of example C will impose V_{CC,X}=16V; V_{EE}=−6V;
The timing t_{OFF,X}=302 ns and t_{ON,X}=287.2 ns.

### Summary of the Examples

The preceding examples are summarized in the following table.

TABLE 1

| Situation | ↑Vₛₒₕ | ↓Vₛₒₕ |
|---|---|---|
| Example A | Change V_{CC}, V_{EE}, t_{ON}, | Change V_{CC}, V_{EE}, t_{ON}, |
| | t_{OFF} | t_{OFF} |
| Example B | ↓t_{ON}, ↑ t_{OFF} | ↑t_{ON}, ↓t_{OFF} |
| Example C | ↑V_{CC} | — |
| | (device is loaded by more | |
| | than 60%) | |
| Example D | ↓V_{EE} | ↑V_{EE} |
| Example E | ↓V_{EE} | ↑V_{EE} |
| | Based on the dVsoh/dt | Based on the dVsoh/dt |
| Example F | ↓V_{EE} | ↑V_{CC} |
| Example G | Reverse conduction | Reverse conduction |
| Example H | Change t_{ON}, t_{OFF} | Change t_{ON}, t_{OFF} |

This disclosure is not limited to the methods, modules, circuitries and computer software described here, which are only examples. The invention encompasses every alternative that a person skilled in the art would envisage when reading this text.

### REFERENCE SIGNS LIST

1: module
2: detection module
3: calculation module
4: actuation module
5: gate driver voltage source
11: semiconductor element
12: control circuitry
21: indexes
22: indexes
31: semiconductor element
32: voltage source
33: gate resistance
CTRL: control signal.

1. A treatment method of a power semiconductor module comprising at least one semiconductor element including a Metal-Oxide-Semiconductor element and/or a Metal-Insulator-Semiconductor element, said method comprising:
a. acquiring a first value V_{soh,0} corresponding to an initial state of health of a gate oxide of the module;
b. acquiring a second value V_{soh,X} corresponding to a current state of health of a gate oxide of the module,
c. deducing
an ON-state gate voltage V_{CC} or an OFF-state gate voltage V_{EE}, and
a delay time of the turn-on t_{off} or a delay time of the turn-off t_{OFF}
in function of said acquired first value V_{soh,0} and said second value V_{soh,X};
d. generating at least one control signal configured to apply the deduced gate voltage V_{CC} or V_{EE} to the module during the deduced delay time t_{ON} or tor.

2. The method according to claim 1, further comprising the following preliminary operation:
switching said at least one semiconductor element
from an ON-state to an OFF-state, according to a control logic signal with a zero or negative gate voltage V_{EE} and with a delay time for the turning-off t_{OFF};
or
from an OFF-state to an ON-state, according to a control logic signal with a positive gate voltage V_{CC} and with a delay time for the turning-on t_{ON}.

3. The method according to claim 1, wherein the sign of the applied gate voltage V_{CC} or V_{EE} depends on the ON/OFF state of said at least one semiconductor element.

4. The method according to claim 1, wherein criteria to deduce the delay time of the turn-on tor; or the delay time of the turn-off t_{OFF} in function of said acquired first value V_{soh,0} and said acquired second value V_{soh,X} includes the following:
if the acquired second value V_{soh,X} is superior to the acquired first value V_{soh,0}, the delay time of the turn-off t_{OFF} is increased with respect to a previous value of the delay time of the turn-off t_{OFF};
if the acquired second value V_{soh,X} is inferior to the acquired first value V_{soh,0}, the delay time of the turn-off t_{OFF} is decreased with respect to a previous value of the delay time of the turn-off t_{OFF}.

5. The method according to claim 1, wherein criteria to deduce the ON-state gate voltage V_{CC} or an OFF-state gate voltage V_{EE} in function of said acquired first value V_{soh,0} and said acquired second value V_{soh,X} includes the following:
if the acquired second value V_{soh,X} is superior to the acquired first value V_{soh,0}, the ON-state gate voltage V_{CC} is increased with respect to a previous value of the ON-state gate voltage V_{CC}, and the increasing is proportional or equal to the difference between the acquired first value V_{soh,0} and the acquired second value V_{soh,X}.

6. The method according to claim 1, wherein criteria to deduce the ON-state gate voltage V_{CC} or an OFF-state gate voltage V_{EE} in function of said acquired first value V_{soh,0} and said acquired second value V_{soh,X} includes the following:
if the acquired second value V_{soh,X} is superior to the acquired first value V_{soh,0}, the OFF-state gate voltage V_{EE} is decreased with respect to a previous value of the OFF-state gate voltage V_{EE};
if the acquired second value V_{soh,X} is inferior to the acquired first value V_{soh,0}, the OFF-state gate voltage V_{EE} is increased with respect to a previous value of the OFF-state gate voltage V_{EE};
if the acquired second value V_{soh,X} is equal to the acquired first value V_{soh,0}, the OFF-state gate voltage V_{EE} is maintained equal to a previous value of the OFF-state gate voltage V_{EE}.

7. The method according to claim 1, wherein criteria to deduce the ON-state gate voltage V_{CC} or an OFF-state gate voltage gate voltage V_{EE} in function of said acquired first value V_{soh,0} and said acquired second value V_{soh,X} includes the following:
if the acquired second value V_{soh,X} is superior to the acquired first value V_{soh,0}, the OFF-state gate voltage V_{EE} is decreased with respect to a previous value of the OFF-state gate voltage V_{EE};
if the acquired second value V_{soh,X} is inferior to the acquired first value V_{soh,0}, the ON-state gate voltage V_{CC} is increased with respect to a previous value of the ON-state gate voltage V_{CC};
if the acquired second value V_{soh,X} is equal to the acquired first value V_{soh,0} the ON-state gate voltage V_{CC} and the OFF-state gate voltage V_{EE} are each reinitialized to their respective value by default.

8. The method according to claim 1, further comprising the following operation:
when a reverse conduction of the semiconductor element is detected, generating at least one control signal configured to apply the deduced gate voltage V_{CC} or V_{EE} to the module.

9. The method according to claim 1, wherein a part of the method forms an iterative loop such that the series of operations b to d are reiterated at least one time, starting from an acquisition of a second value V_{SOH,X+1} a second time.

10. The method according to claim 9, wherein at least two second values V_{soh,X} and V_{soh,X+1} are acquired during the lifetime of the module, and wherein criteria to deduce the ON-state gate voltage V_{CC} or an OFF-state gate voltage V_{EE} in function of said acquired first value V_{soh,0} and said acquired second values V_{soh,X} and V_{soh,X+1} includes the following:
if the temporal derivative of the said acquired second values dV_{soh,X}/dt is positive, the ON-state gate voltage V_{CC} is decreased with respect to a previous value of the ON-state gate voltage V_{CC} and/or the OFF-state gate voltage V_{EE} is decreased with respect to a previous value of the OFF-state gate voltage V_{EE};
if the temporal derivative of the said acquired second values dV_{soh,X}/dt is negative, the ON-state gate voltage V_{CC} is increased with respect to a previous value of the ON-state gate voltage V_{CC} and/or the OFF-state gate Voltage V_{EE} is increased with respect to a previous value of the OFF-state gate voltage V_{EE}.

11. The method according to claim 1, wherein criteria to deduce the delay time of the turn-on t_{ON} or the delay time of the turn-off t_{OFF} is further dependent from the ON-state gate voltage V_{CC} and/or the OFF-state gate voltage V_{EE}.

12. A power semiconductor module comprising a single Metal-Oxide-Semiconductor element or a set of Metal-Oxide-Semiconductor elements or a single Metal-Insulator-Semiconductor element or a set of Metal-Insulated-Semiconductor elements, said module being arranged to implement the method according to claim 1.

13. Computer software comprising instructions to implement the method according to claim 1 when the software is executed by a processor.

14. Computer-readable non-transient recording medium on which a software is registered to implement the method according to claim 1 when the software is executed by a processor.
